(19) United States
(12) Patent Application Publication
(10) Pub. No.: US 2015/0381116 A1
(43) Pub. Date: Dec. 31, 2015

(54) POWER AMPLIFIER AND CLASS AB POWER AMPLIFIER

(71) Applicant: Realtek Semiconductor Corp., HsinChu (TW)

(72) Inventor: Chien-Ming Wu, Hsinchu County (TW)

(21) Appl. No.: 14/742,666

(22) Filed: Jun. 17, 2015

(30) Foreign Application Priority Data
Jun. 27, 2014 (TW) 103122307

(51) Int. Cl. H03F 1/26; H03F 3/45; H03F 3/21

(52) U.S. Cl. CPC H03F 1/26; H03F 3/21; H03F 3/45179; H03F 2200/222; H03F 2203/45156

(57) ABSTRACT

A power amplifier includes a gain stage, an output stage and a first capacitor. The gain stage is arranged for receiving at least a first input signal to generate a first pair of control signals. The output stage includes a first node and a second node for receiving the first pair of control signals, and the output stage generates a first output signal according to the first pair of control signals. The first capacitor is coupled between the first node and the second node.

### BACKGROUND OF THE INVENTION

1. Field of the Invention

The present invention relates to a power amplifier, and more particularly, to a power amplifier which can reduce common mode noise.

2. Description of the Prior Art

A common mode noise is generated when a line driver within an Enthernet chip outputs a signal. This common mode noise is sent to a backend network wire and generates ElectroMagnetic Interference (EMI). A common way to eliminate the common mode noise is to add common mode choke or apply Bob Smith termination resistors in the signal transmitting path; however, these methods increase manufacturing costs.

### SUMMARY OF THE INVENTION

One of the objectives of the present invention is to provide a power amplifier which can effectively reduce common mode noise.

According to an embodiment of the present invention, a power amplifier comprises: a gain stage, an output stage and a first capacitor. The gain stage is arranged for receiving a first input signal to generate a first pair of control signals. The output stage comprises a first node and a second node for receiving the first pair of control signals, and generates a first output signal according to the first pair of control signals. The first capacitor is coupled between the first node and the second node.

According to another embodiment of the present invention, a class AB power amplifier comprises a gain stage, an output stage, a first capacitor and a second capacitor. The gain stage is arranged for receiving a first input signal and a second input signal for generating a first pair of control signals and a second pair of control signals, wherein the first input signal and the second input signal are differential inputs. The output stage comprises a first node and a second node for receiving the first pair of control signals, and generates a first output signal according to the first pair of control signals. The output stage further comprises a third node and a fourth node for receiving the second pair of control signals, and generates a second output signal according to the second pair of control signals, wherein the first output signal and the second output signal are differential outputs. The first capacitor is coupled between the first node and second node, and the second capacitor is coupled between the third node and the fourth node.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a power amplifier according to an embodiment of the present invention.

FIG. 2 is a diagram illustrating a detailed circuit architecture of a power amplifier according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should not be interpreted as a close-ended term such as “consist of”. Also, the term “couple” is intended to mean either an indirect or direct electrical connection. Accordingly, if one device is coupled to another device, that connection may be through a direct electrical connection, or through an indirect electrical connection via other devices and connections.

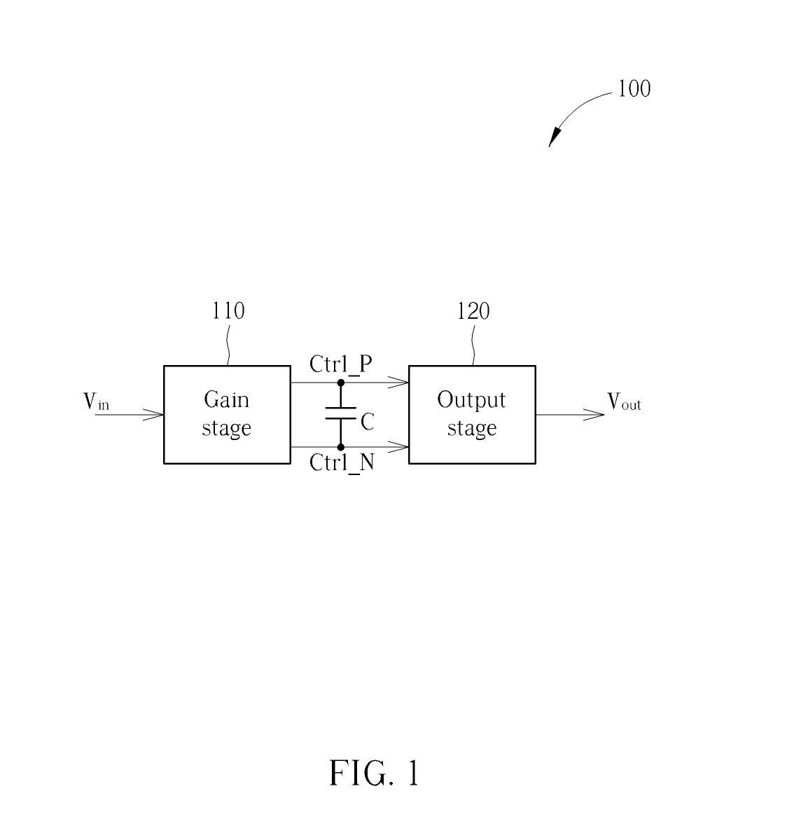

FIG. 1 is a diagram illustrating a power amplifier 100 according to an embodiment of the present invention. The power amplifier 100 comprises a gain stage 110, an output stage 120 and a capacitor C. In this embodiment, the power amplifier 100 is a class AB power amplifier, and is installed in an Ethernet chip, but this is not a limitation of the present invention.

In the operation of the power amplifier 100, the gain stage 100 receives an input signal yin to generate a pair of control signals Ctrl_P and Ctrl_N to the output stage 120, and the output stage 120 generates an output signal Vout according to the pair of control signals Ctrl_P and Ctrl_N. The capacitor C is disposed between a first node and a second node within the output stage 120 and provides a high capacitance, wherein the first node and the second node are for receiving the pair of control signals Ctrl_P and Ctrl_N. In this embodiment, the capacitance of the capacitor C is approximately between 500 fF and 3 pF.

Due to the control signals Ctrl_P and Ctrl_N generated by the output stage 110 oscillating when the class AB power amplifier 100 is in operation, the capacitor C can make the high frequency components of the control signals Ctrl_P and Ctrl_N approximate to the class A power amplifier operation. Conventionally, the reason the class AB power amplifier can suppress more common mode noise is because it consumes more power, but the class A power amplifier 100 in the present invention can suppress the common mode noise without increasing power consumption. Therefore, more power can be saved compared with the conventional class A power amplifier.

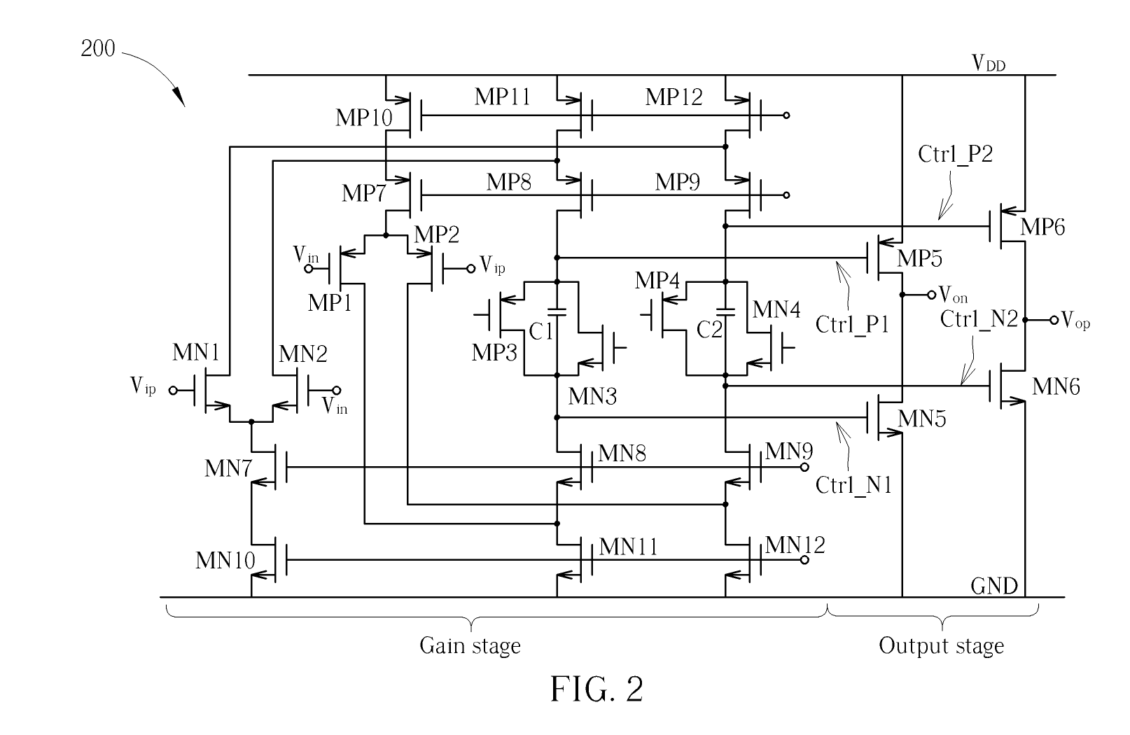

FIG. 2 is a diagram illustrating a detailed circuit architecture of a power amplifier according to an embodiment of the present invention. Similar to the power amplifier 100 shown in FIG. 1, the power amplifier 200 shown in FIG. 2 comprises a gain stage, an output stage and two capacitors C1 and C2. The gain stage comprises N type transistors MN1 to MN4 and MN7 to MN12, and P type transistors MP1 to MP4 and MP7 to MP12 for receiving a first input signal Vin and a second input signal Vip, respectively, wherein the first input signal Vin and the second input signal Vip are differential inputs. The output stage comprises N type transistors MN5 and MN6 and P type transistors MP5 and MP6 disposed between the supply voltage V_{DD} and the ground voltage GND, wherein a drain terminal of the P type transistor MP5 is connected to a drain terminal of the N type transistor MN5, and gate terminals of the P type transistor MP5 and the N type transistor MN5 serve as a first node and a second node, respectively, for receiving a first pair of control signals Ctrl_P1 and Ctrl_N1 to generate a first output signal Von. Similarly, a drain terminal of the P type transistor MP6 is connected to a drain terminal of the N type transistor MN6, and gate terminals of the P type transistor MP6 and the N type transistor MN6 serve as a third node and a fourth node, respectively, for receiving a second pair of control signals Ctrl_P2 and Ctrl_N2 to generate a second output signal Vop, wherein the first output signal Von and the second output signal Vop are differential outputs.

The capacitor C1 is disposed between the gate terminals of the P type transistor MP5 and the N type transistor MN5 for providing a high capacitance, and the capacitor C2 is disposed between the gate terminals of the P type transistor MP6 and the N type transistor MN6 for providing a high capacitance. In this embodiment, the capacitance of the capacitor C1 and the capacitor C2 are both higher than 500 fF; more specifically, approximately between 500 fF and 3 pF.

In this embodiment, the power amplifier 200 operates as a class AB power amplifier; i.e. in the gain stage, the bias voltage of the gate terminals of the N type transistors MN3, MN4 and the P type transistors MP3, MP4 can be controlled to make the power amplifier 200 operate as a class AB power amplifier. The implementation of the gain stage of the power amplifier 200 can be achieved in many ways, however, and is not limited to the architecture shown in FIG. 2.

When the power amplifier 200 operates as a class AB power amplifier, the first pair of control signals Ctrl_P1 and Ctrl_N1 and the second pair of control signals Ctrl_P2 and Ctrl_N2 generated by the gain stage oscillate. At this time, the capacitors C1 and C2 can make the high frequency components of the first pair of control signals Ctrl_P1 and Ctrl_N1 and the second pair of control signals Ctrl_P2 and Ctrl_N2 approximate to a class A power amplifier operation to suppress the common mode noise while saving mode power compared to a conventional class A power amplifier. In a simulation result, assuming the capacitances of the capacitors C1 and C2 are 1 pF, the common mode noise of the power amplifier 200 can be reduced from 10 to 20 dB.

The power amplifier 200 shown in FIG. 2 is a differential topology, but this is only for illustrative purposes. One skilled in this art should understand that the present invention can be applied to a signal input topology such as that shown in FIG. 1.

Briefly summarized, in the power amplifiers of the present invention, a capacitor with high capacitance is disposed between the gate terminals of the N type transistor and the P type transistor of the output stage to make the power amplifier suppress the common node noise without increasing the power consumption, which can solve the problems of the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power amplifier, comprising:
a gain stage, wherein the gain stage is arranged for receiving at least a first input signal to generate a first pair of control signals;
an output stage, wherein the output stage comprises a first node and a second node for receiving the first pair of control signals, and generates a first output signal according to the first pair of control signals; and
a first capacitor, coupled between the first node and the second node.

2. The power amplifier of claim 1, wherein the output stage comprises:
a P type transistor; and
an N type transistor, wherein a drain terminal of the N type transistor is connected to a drain terminal of the P type transistor;
wherein gate terminals of the P type transistor and the N type transistor serve as the first node and the second node for receiving the first pair of control signals, the drain terminal of the N type transistor is arranged for outputting the first output signal, and the first capacitor is disposed between the gate terminals of the P type transistor and the N type transistor.

3. The power amplifier of claim 1, wherein a capacitance of the capacitor is higher than 500 fF.

4. The power amplifier of claim 1, wherein the gain stage receives the first input signal and a second input signal to generate the first pair of control signals and a second pair of control signals, and the output stage further comprises a third node and a fourth node for receiving the second pair of control signals to generate a second output signal, wherein the first input signal and the second input signal are differential inputs, and the first output signal and the second output signal are differential outputs, and the power amplifier further comprises:
a second capacitor, coupled between the third node and the fourth node.

5. The power amplifier of claim 4, wherein the output stage comprises:
a first P type transistor;
a first N type transistor, wherein a drain terminal of the first N type transistor is connected to a drain terminal of the first P type transistor, gate terminals of the first P type transistor and the first N type transistor serve as the first node and the second node for receiving the first pair of control signals, and the drain terminal of the first N type transistor is arranged for outputting the first output signal;
a second P type transistor; and
a second N type transistor, wherein a drain terminal of the second N type transistor is connected to a drain terminal of the second P type transistor, gate terminals of the second P type transistor and the second N type transistor serve as the third node and the fourth node for receiving the second pair of control signals, and the drain terminal of the second N type transistor is arranged for outputting the second output signal.

6. The power amplifier of claim 1, wherein a capacitance of the first capacitor and a capacitance of the second capacitor are both higher than 500 fF.

7. The power amplifier of claim 1, wherein the power amplifier is a class AB power amplifier.

8. A class AB power amplifier, comprising:
a gain stage, arranged for receiving a first input signal and a second input signal to generate a first pair of control signals and a second pair of control signals, wherein the first input signal and the second input signal are differential inputs;
an output stage, wherein the output stage comprises a first node and a second node for receiving the first pair of control signals, and generates a first output signal according to the first pair of control signals; and the output stage further comprises a third node and a fourth node for receiving the second pair of control signals, and generates a second output signal according to the second pair of control signals, wherein the first output signal and the second output signal are differential outputs;
a first capacitor, coupled between the first node and the second node; and
a second capacitor, coupled between the third node and the fourth node.

9. The power amplifier of claim 8, wherein the output stage comprises:
a first P type transistor;
a first N type transistor, wherein a drain terminal of the first N type transistor is connected to a drain terminal of the first P type transistor, gate terminals of the first P type transistor and the first N type transistor serve as the first node and the second node for receiving the first pair of control signals, and the drain terminal of the first N type transistor is arranged for outputting the first output signal;
a second P type transistor; and
a second N type transistor, wherein a drain terminal of the second N type transistor is connected to a drain terminal of the second P type transistor, gate terminals of the second P type transistor and the second N type transistor serve as the third node and the fourth node for receiving the second pair of control signals, and the drain terminal of the second N type transistor is arranged for outputting the second output signal.

10. The power amplifier of claim 8, wherein a capacitance of the first capacitor and a capacitance of the second capacitor are both higher than 500 fF.
